(19) United States
(12) Patent Application Publication
(10) Pub. No.: US 2015/0364498 A1
(43) Pub. Date: Dec. 17, 2015

(54) BACK BIASED TRANSISTOR AND CURRENT SOURCE BIASING

(71) Applicant: International Business Machines Corporation, Armonk, NY (US)

(72) Inventors: Eric J. Lukes, Stewartville, MN (US); Nghia V. Phan, Rochester, MN (US); Patrick L. Rosno, Rochester, MN (US); Dereje G. Yilma, Rochester, MN (US)

(21) Appl. No.: 14/306,334

(22) Filed: Jun. 17, 2014

(51) Int. Cl. H01L 27/12; H01L 29/06; G06F 17/50; H01L 29/66; H01L 21/762; H01L 21/84; H01L 29/78; H01L 29/36

(52) U.S. Cl. CPC H01L 27/1211; H01L 29/785; H01L 29/0649; H01L 29/36; H01L 29/66795; H01L 21/76224; H01L 21/845; G06F 17/5068

(57) ABSTRACT

A semiconductor chip device may include a silicon on insulator (SOI) base, a first transistor, and a voltage device. The SOI base may include a semiconductor substrate having a first doped layer and a second doped layer directly on the first doped layer, a buried oxide layer directly on the second doped layer, and a first moat electrically isolating a first bias region of the second doped layer. The first bias region may be electrically coupled to a current source. The first transistor may be formed above the buried oxide layer and the first bias region. The first transistor may include a first drain a first source a first body a first gate and a first back gate. The voltage device may be electrically coupled to the first back gate and the first gate and configured to maintain a voltage difference between the first gate and the first back gate.

### BACKGROUND

The present disclosure generally relates to semiconductor devices, and more specifically, to back-gate biased transistors for mirroring a current source to a circuit load.

FinFETs, fully depleted silicon on insulator (FDSOI) transistors, and other transistors may be constructed on a silicon on insulator (SOI) base above a buried oxide layer (BOX). A thin gate dielectric and a gate conductor may contact a body area of SOI transistors to create a channel allowing current to flow between a drain and a source. These transistors may utilize a global bias in the SOI base, to create a reference plane for the transistors and improve performance of transistors placed on the SOI base.

### SUMMARY

According to embodiments of the present disclosure a semiconductor chip device may include a silicon on insulator (SOI) base, a first transistor, and a voltage device. The SOI base may include a semiconductor substrate having a first doped layer and a second doped layer directly on the first doped layer. The SOI base may include a buried oxide layer directly on the second doped layer, and a first moat electrically isolating a first bias region of the second doped layer from other areas of the second doped layer, where the first bias region is electrically coupled to a current source. The first transistor may be formed above the buried oxide layer and the first bias region. The first transistor may include a first drain, a first source, a first body, and a first gate. The first body may be between the first drain and first source and have at least a top side and bottom side. The bottom side may directly contact the buried oxide layer.

The first gate may be on at least the top side of the first body, the first gate electrically coupled to the current source. The first back gate may be on the bottom side of the first body and may include the buried oxide layer as a gate dielectric and the first bias region as a gate electrode. The voltage device may be formed above the buried oxide layer and the first bias region and may be electrically coupled to the first back gate and the first gate. The voltage device may be configured to maintain a voltage difference between the first gate and the first back gate. The voltage difference between the first gate and the first back gate may be approximately zero.

The first bias region may include a first substrate contact electrically coupled to the current source via the first substrate contact. The first substrate contact may have a first dopant concentration greater than a first bias dopant concentration of the first bias region. The voltage device may be a second transistor formed above the buried oxide layer and the first bias region. The second transistor may include a second drain, a second source, a second body between the second drain and second source, a second gate, and a second back gate. The second body may have at least a top side and bottom side and the bottom side may directly contact the buried oxide layer. The second gate may be on at least the top side of the second body. The second back gate may be on the bottom side of the second body and include the buried oxide layer as a gate dielectric and the first bias region as a gate electrode.

The first drain, the first gate, and the second gate may be electrically coupled to one another, to the first bias region, and to the current source. The first source and second source may be electrically coupled to one of a ground reference or a first potential and the second drain may be electrically coupled to a circuit load. The first transistor may receive a first current from the current source and the circuit load may receive a second current, based on the first current, from the second transistor.

The SOI base may include a second moat electrically isolating a second bias region of the second doped layer from other areas of the second doped layer. The second bias region may be electrically coupled to the current source. The second transistor may be formed above the buried oxide layer and the second bias region. The second gate may be electrically coupled to the first gate, the first drain, the first bias region, and the second bias region. The second bias region may include a second substrate contact. The first drain, the first gate, the current source, and the second gate may be electrically coupled to the second bias region via the second substrate contact. The first and second transistors may be fully depleted SOI transistors. The first and second transistors may be FinFETs.

A method of manufacturing a transistor device may include forming a first doped layer, forming a second doped layer directly on the first doped layer, forming a buried oxide layer directly on the second doped layer, forming a first moat enclosing a first bias region of the second doped layer, and forming a first transistor above the buried oxide layer and the first bias region. The first moat may electrically isolate the first bias region from other areas of the second doped layer. The first transistor may include a first drain, a first source, a first body, a first gate, and a first back gate. The method may include forming a voltage device above the buried oxide layer and the first bias region, electrically coupling the first bias region and the first gate to a current source, and electrically coupling the first gate and the first back gate to a voltage device, the voltage device configured to maintain a voltage difference between the first gate and the first back gate.

A design structure readable by a machine used in design, manufacture, or simulation of an integrated circuit, the design structure may include a silicon on insulator (SOI) base, a first transistor, and a voltage device. The SOI base may include a semiconductor substrate having a first doped layer and a second doped layer directly on the first doped layer. The SOI base may include a buried oxide layer directly on the second doped layer, and a first moat electrically isolating a first bias region of the second doped layer from other areas of the second doped layer, where the first bias region is electrically coupled to a current source. The first transistor may be formed above the buried oxide layer and the first bias region. The first transistor may include a first drain, a first source, a first body, and a first gate. The first body may be between the first drain and first source and have at least a top side and bottom side. The bottom side may directly contact the buried oxide layer.

The first gate may be on at least the top side of the first body, the first gate electrically coupled to the current source. The first back gate may be on the bottom side of the first body and may include the buried oxide layer as a gate dielectric and the first bias region as a gate electrode. The voltage device may be formed above the buried oxide layer and the first bias region and may be electrically coupled to the first back gate and the first gate. The voltage device may be configured to maintain a voltage difference between the first gate and the first back gate. The voltage difference between the first gate and the first back gate may be approximately zero. The design structure may reside on storage medium as a data format used for the exchange of layout data of integrated circuits.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIGS. 1A-1B depict a circuit diagram showing a transistor assembled with a voltage device according to embodiments of the present disclosure.

FIGS. 2A-2B depict cross section views of a semiconductor chip having a circuit on an SOI base according to embodiments of the present disclosure.

FIGS. 3A-3B depicts cross section views of a semiconductor chip having a circuit on an SOI base according to embodiments of the present disclosure.

FIG. 4 depicts a flowchart of a method of manufacturing a transistor circuit according to embodiments of the present disclosure.

FIG. 5 is a flow diagram of a design process used in semiconductor design, manufacture, and/or test.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to back-gate biased transistors. While the present disclosure is not necessarily limited to such applications, various aspects of the disclosure may be appreciated through a discussion of various examples using this context.

While the same nomenclature and same numbers may be used to identify elements throughout the disclosure, this practice is not intended to limit the scope of the disclosure. Identified elements in one figure may not be identical to other same named or identified elements in other figures.

Semiconductor chips may be constructed using silicon on insulator (SOI) techniques. SOI techniques may include forming a semiconductor substrate layer (e.g. silicon, germanium) on which a buried oxide layer (BOX) is formed. Layered on top of the BOX is a silicon (or other suitable material) body layer. With the semiconductor body layer, SOI transistors may be formed by doping various regions of the semiconductor body layer with varying dopant concentrations and types and adding electrical contacts to the various doped regions.

SOI transistors may include fully depleted SOI (FDSOI) devices and metal-oxide-semiconductor field-effect transistor (MOSFET) devices such as a FinFET or other devices. In a device such as a FinFET, a thin gate dielectric and a gate conductor may wrap up and over a fin to create a gate over a body area of the FinFET. The gate, when active, may create a channel on three sides of the fin (over the top and opposing sidewalls of the channel) allowing current to flow between a drain and a source. The bottom of the fin sits atop the oxide and may not be gated.

In a device such as a FDSOI, the transistor may have an ultra-thin semiconductor body with a gate dielectric and a gate conductor sitting over the body. The gate, when active, may create a channel on the top side of the body where the gate conductor and gate dielectric sit. The bottom of the body may not have a gate. Therefore, minimal current flows through bottom portion of the body area when other gates are active.

Transistor performance may be improved, in various types of circuits, by utilizing a back channel for SOI transistors by biasing the semiconductor substrate directly under the BOX. The biased semiconductor substrate may act as an additional gate conductor (a back gate) and the BOX may act as the gate dielectric which, when active, creates a channel, in the case of a FinFET, on the bottom side of the fin body and, in the case of an FDSOI, on the bottom side of the body. Adding a potential to the back side of a semiconductor device to activate or deactivate a channel (depending on whether the transistor is a p-type transistor or n-type transistor) on the bottom side of the transistor may be referred to as back biasing. However, applying a global back bias along the semiconductor substrate beneath the BOX may not be suitable for every circuit contained on the SOI base. For example, different circuits may have varying limitations on voltage, which may be suitable for one circuit on the SOI but will cause issues for other circuits on the SOI. Further, noise may couple into the biased semiconductor substrate which may result in problems for low noise tolerant circuits such as high gain amplifier circuits. Variations in the potential across the semiconductor substrate can also increase chip mismatch between devices.

Therefore, a local bias may be used, in lieu of a global bias, to create one or more locally enclosed bias regions which can be contacted and driven to a potential to create a back gate and which may be configured for local circuits. A current reference/current mirror circuit could benefit from this by generating a local bias for the back gate of the current reference/mirror circuit. This may be accomplished by using the current reference bias to be the bias of the back gate such that the back gate becomes part of the biasing of the current reference. The back gate may then be part of the feedback loop generating the ultimate voltage of the current reference bias. This may improve current reference mirror performance such as current mirror head room and may also be improved between transistor devices, which are at a distance away from each other, by applying the same bias to one or more bias regions over which the devices sit.

A semiconductor chip device may include a SOI base including a semiconductor substrate having a first doped layer and a second doped layer directly on the first doped layer. The SOI base may include a buried oxide layer directly on the second doped layer and a first moat electrically isolating a first bias region of the second doped layer from other areas of the second doped layer. The first bias region may be electrically coupled to a current source. The semiconductor chip device may include a first transistor formed above the buried oxide layer and the first bias region. The first transistor may include a first drain, a first source, and a first body between the first drain and first source. The first body may have at least a top side and bottom side, the bottom side may directly contact the buried oxide layer. The transistor may include a first gate on at least the top side of the first body. The transistor may include a first back gate on the bottom side of the first body, the first back gate including the buried oxide layer as a gate dielectric and the first bias region as a gate electrode.

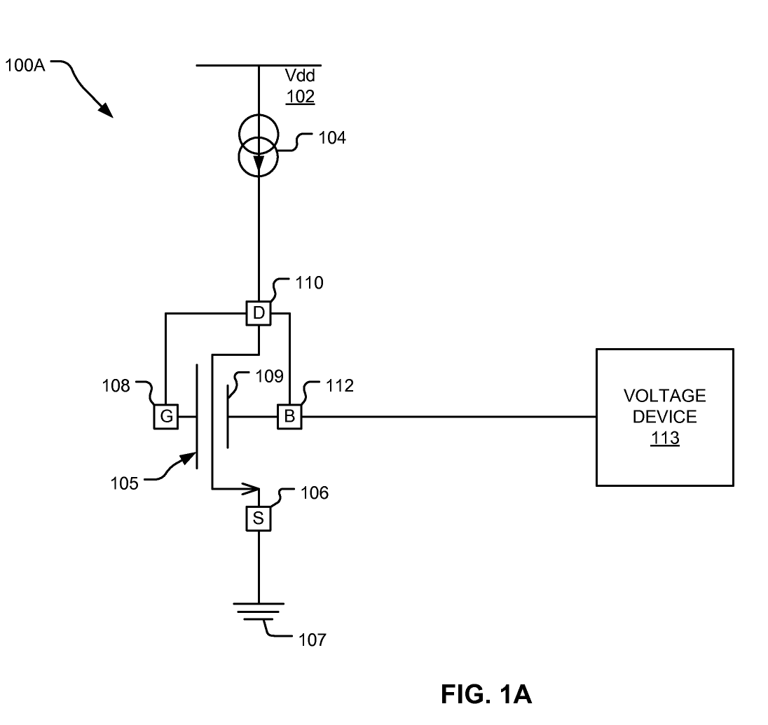

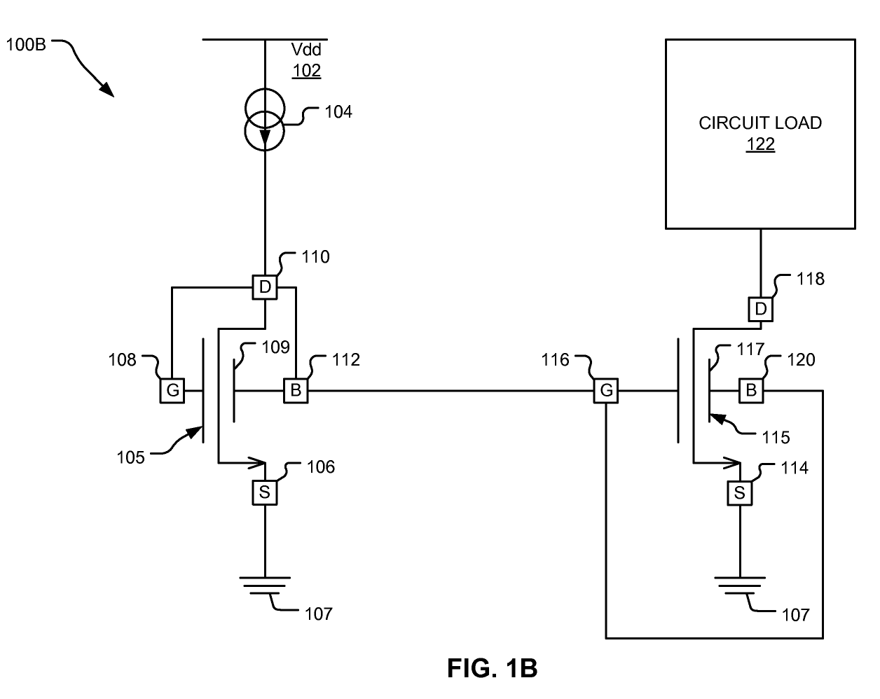

Referring now to FIG. 1A, a circuit diagram 100A may be seen showing a pair of devices according to embodiments of the present disclosure. The circuit diagram 100A may include a first potential 102 and a current source 104. The circuit diagram 100B may include a first transistor 105 having a first drain 110, a first gate 108, a first source 106, a back gate 109 and a first bias region 112. The circuit diagram includes a voltage device 113 electrically coupled to the first bias region 112, the first gate 108, and the first drain 110.

The first transistor 105 may be selected as multiple types of transistors. In embodiments, the first transistor 105 may be a field effect transistor, fully depleted SOI transistor, multi-gate field effect transistor, FinFETs or other suitable transistors. The first drain 110 and the first gate 108 may be electrically coupled together and to the current source 104. The current source 104, the first drain 110, and the first gate 108 may also be electrically coupled to a first bias region 112.

The first bias region 112 may be a single region contained in a section of doped silicon layer in the SOI base, as described herein. The first source 106 and second source 114 may both be electrically coupled to a ground reference 107. The first bias region 112 may be biased by electrically coupling it to the current source 104 which may induce a specific potential in the first bias region 112, described further herein. The biased first bias region 112 may create a first back gate 109 within the first transistor, described further within.

The voltage device 113 may be a transistor or other suitable device which is electrically coupled to the current source 104, first bias region 112, the first back gate 109, the first gate, and the first drain 110. The voltage device may be configured to maintain a voltage difference between the first back gate 109 and the first gate 108. Because the voltage device 113, the first gate 108, and the first back gate 109 are each electrically coupled to the current source 104, the voltage device 113 may maintain the voltage difference between the first gate 108 and the first back gate 109 even as the current source 104 changes. In embodiments, the voltage difference may be maintained as approximately zero, regardless of changes in the current source 104. This may result in a first transistor 105 having approximately equal potential on all sides of the channel, which may improve performance, described further herein.

The circuit diagram 100A depicts a first transistor 105 which is an NFET (or N-channel) transistor. In embodiments, the transistor may be a PFET (or P-channel) transistor where the first drain 110, the first gate 108, first biased region 112, and the voltage device are electrically coupled to a common ground reference 107 and where the first and second sources 106, 114 are electrically coupled to the first potential 102.

Referring now to FIG. 1B, a circuit diagram 100B may be seen showing a pair of transistors assembled in a current reference and current mirror circuit, according to embodiments of the present disclosure. The circuit diagram 100B may include a first potential 102 and a current source 104. The circuit diagram 100B may include a first transistor 105 having a first drain 110, a first gate 108, a first source 106, a first back gate 109 and a first bias region 112. The circuit diagram 100B may include a second transistor 115 having a second drain 118, a second gate 116, a second source 114, a second back gate 117 and a second bias region 120. The circuit diagram 100B may also include a circuit load 122. The current reference and current mirror circuit may receive the first current from a current source 104 and apply a second current, based on the first current, to the circuit load 122. In embodiments, the first current may be approximately the same as the second current. In certain embodiments, second transistor 115 may amplify or attenuate the first current so that the second current may be greater than or less than the first current. While a current reference and current mirror circuit is used to illustrate one example of how a back-gate may be implemented, other suitable circuits may be used.

The first and second transistors 105, 115 may be selected as multiple types of transistors. In embodiments, the first and second transistors 105, 115 may be field effect transistors, fully depleted SOI transistors, multi-gate field effect transistors, FinFETs or other suitable transistors. The first drain 110 and the first gate 108 may be electrically coupled together and to the current source 104. The current source 104, the first drain 110, and the first gate 108 may also be electrically coupled to a first bias region 112.

The second gate 116 may be electrically coupled to the first bias region 112, the first drain 110, the first gate 108, and the second bias region 120. In embodiments, the first bias region 112 and the second bias region 120 may be a single region contained in a section of doped silicon layer in the SOI base, as described herein. In certain embodiments, the first bias region 112 and second bias region 120 may be separate regions each contained in a separate section of doped silicon in the SOI base, as described herein.

The first source 106 and second source 114 may both be electrically coupled to a ground reference 107. The second drain 118 may be electrically coupled to the circuit load 122.

Described further herein, the first bias region 112 and the second bias region 120 may be biased by electrically coupling each to the current source 104. The current source 104 may induce a specific potential in the first and second bias regions 112, 120 described further herein. The first and second bias regions may result in creating a first back gate 109 within the first transistor 105 and a second back gate 117 within the second transistor 115. A voltage difference of approximately zero may be maintained between the first and second gates 108, 116 and the first and second back gates 112, 120, as each are electrically coupled together and to the current source 104. This may result in the first and second transistors 105, 115 having approximately equal potential on all sides of the channel, which may improve performance.

The circuit diagram depicts first and second transistors 105, 115 which are NFET (or N-channel) transistors. In embodiments, the transistors may be PFET (or P-channel) transistors where the first drain 110, the first gate 108, second gate 116, first biased region 112, and second biased region 120 are electrically coupled to a common ground reference 107 and where the first and second sources 106, 114 are electrically coupled to the current source 104. The second drain may be coupled to the circuit load 122.

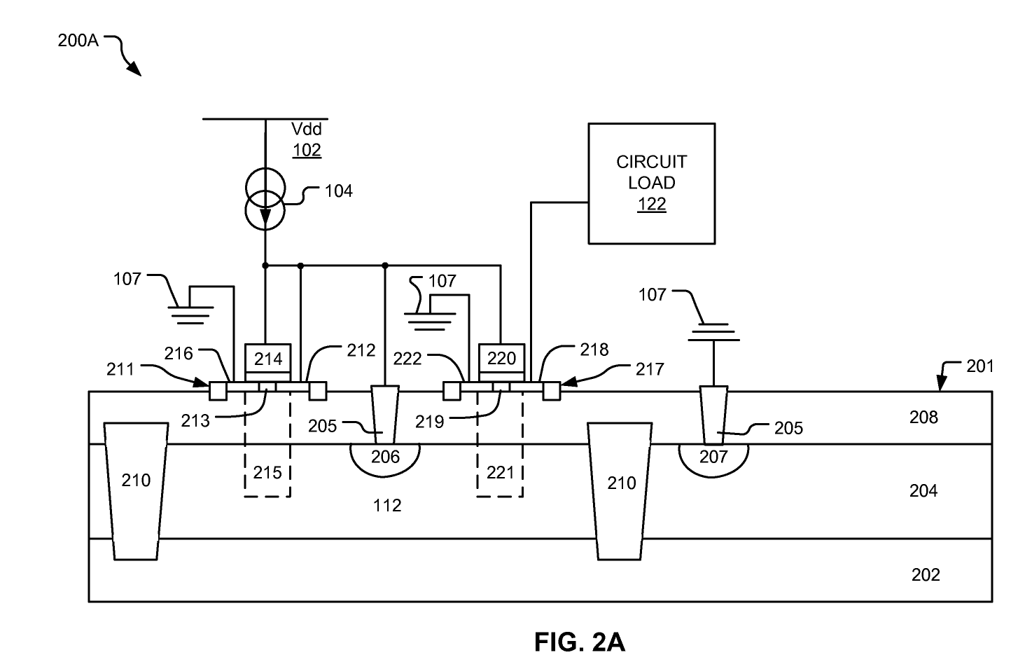

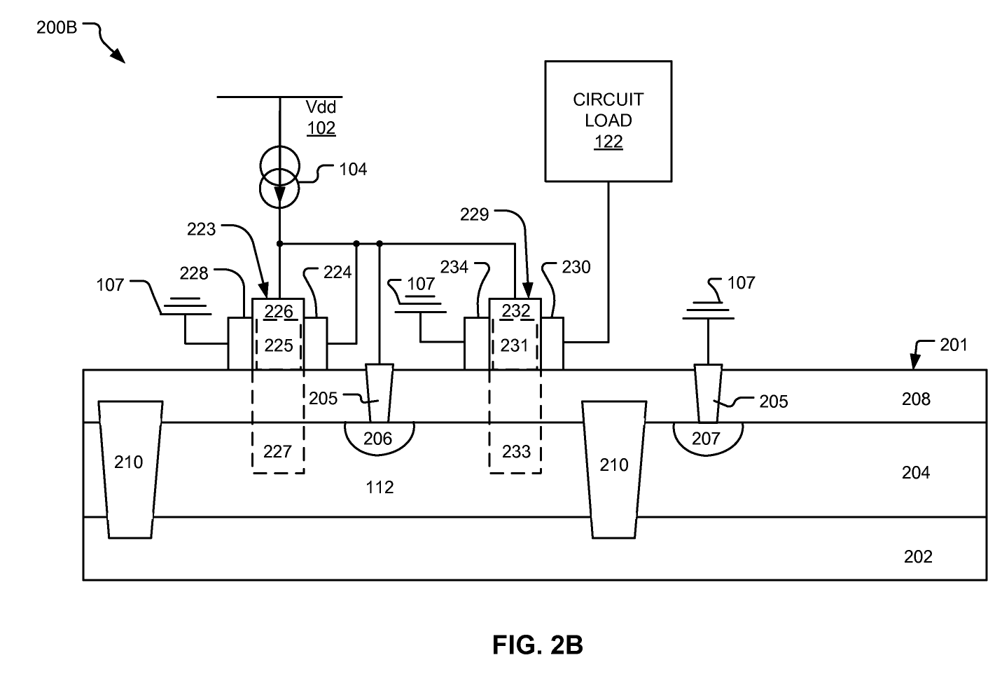

Referring now to FIG. 2A, a cross section view of a semiconductor chip 200A having a circuit on an SOI base 201 is depicted according to embodiments of the present disclosure. The cross section may include an SOI base 201 having a semiconductor substrate and a buried oxide layer 208. The semiconductor substrate may include a first doped layer 202 and a second doped layer 204. The second doped layer 204 may include a first moat 210, a first bias region 112, and a first substrate contact 206. The cross section may include a first FDSOI transistor 211 and a second FDSOI transistor 217.

The SOI base 201 may provide a base for formation of one or more SOI transistors of various types as described herein. The first and second doped layers 202, 204 may be constructed from conductive materials, such as doped silicon, or other suitable semiconductor material including but not limited to silicon-germanium In embodiments, the first doped layer 202 and the second doped layer 204 may be constructed from P doped silicon or N doped silicon. In embodiments, the first doped layer may be constructed from P doped silicon to form a P− layer. In embodiments, the second doped layer 204 may be constructed from N doped silicon to form an N+ layer. The buried oxide layer 208 may be constructed from silicon doped with oxygen such as SiO², or other dielectrics such as HfO², such that an oxide layer is formed, which electrically isolates the first and second doped layers 202, 204 from layers or components placed on the buried oxide layer 208.

The first moat 210 may enclose a first bias region 112 of the second doped layer 204 and electrically isolate the first bias region 112 from other areas of the second doped layer 204. The first moat 210 may be constructed from dielectric materials, such as a silicon dioxide or other suitable insulating materials. The first moat 210 may be inserted into the SOI base to enclose the first bias region 112 and electrically insulate the first bias region from other areas in the second doped layer.

The first bias region 112 may be biased to a specific potential when insulated from other areas of the second doped layer 204. The first bias region 112 may be biased by electrically coupling the first bias region 112 to the current source 104 which induces a specific potential. The first bias region may be electrically coupled via a first substrate contact 206 and a conductive contact 205.

The first substrate contact 206 may be a portion of doped silicon included in the first bias region 112. In embodiments, the first substrate contact 206 may be more heavily doped than the first bias region 112 to improve conductivity to the first bias region 112 and improve biasing. In certain embodiments, the first dopant concentration may be approximately the same as the first bias dopant concentration. The conductive contact 205 may be conductive material inserted into the buried oxide layer 208 to allow for electrical connection to the current source 104. In embodiments, the first doped layer 202 may also be biased to the ground reference 107, which may allow for improved biasing of the second doped layer 204.

The area of the second doped layer 204 outside of the first bias region 112 may also have a bias. In embodiments, the area of the second doped layer 204 outside of the first bias region 112 may be electrically coupled to the ground reference 107 via a ground substrate contact 207 to apply a ground bias outside of the first bias region 112. The ground substrate contact 207 may be the same or substantially similar as the first substrate contact 206.

The first and second FDSOI transistors 211, 217 may be the same or substantially similar to the FDSOI transistors as described herein. The first and second FDSOI transistors 211, 217 may be positioned above the buried oxide layer 208 and the first bias region 112. The buried oxide layer 208 may be relatively thin for the first and second FDSOI transistors 211, 217. In embodiments, the buried oxide layer 208 may be approximately 145 nanometers thick. In certain embodiments, the buried oxide layer may be constructed between a range of 10 to 25 nanometers thick. The first FDSOI transistor 211 may include a first drain 212, a first source 216, a first body 213, and a first gate 214. The first body 213 may be between the first drain 212 and first source 216. The first body 213 may have at least a top side and bottom side, the bottom side directly contacting the buried oxide layer 208. The first drain 212 and the first gate 214 may be electrically coupled to one another, to the first bias region 112, and to a current source 104. The first source 216 may be electrically coupled to a ground reference 107.

The second FDSOI transistor 217 may include a second drain 218, a second source 222, a second body 219, and a second gate 220. The second body 219 may be between the first drain 212 and first source 216. The second body 219 may have at least a top side and bottom side, the bottom side directly contacting the buried oxide layer 208. The second gate 220 may be electrically coupled to the first gate 214, the first drain 212, and the first bias region 112. The second drain 218 may be electrically coupled to a circuit load 122. The second source 222 may be electrically coupled to the ground reference 107.

By biasing the first bias region 112 to a specific potential, and electrically coupling the first and second gates 214, 220 to the first bias region 112. A first back gate 215 and a second back gate 221 may be created on the bottom side of the first and second body 213, 219, where the first bias region 112 may act as a gate electrode and the buried oxide layer 208 may act as a gate dielectric. By connecting the first bias region 112, the first gate 214, the second gate 220, the first back gate 215 and the second back gate 221 to the current source 104, a voltage difference of approximately zero may be maintained between the first and second gate 214, 220, and the first and second back gate 215, 221. This may increase performance for the first and second FDSOI transistors 211, 217.

The cross section depicts first and second FDSOI transistors 211, 217 which are NFET transistors. In embodiments, the transistors may be PFET transistors as described herein.

Referring now to FIG. 2B, a cross section view of a semiconductor chip 200B having a circuit on an SOI is illustrated according to embodiments of the present disclosure. The cross section may include an SOI base 201 having a first doped layer 202, a second doped layer 204, and a buried oxide layer 208. The second doped layer 204 may include a first moat 210, a first bias region 112, and a first substrate contact 206. The cross section may include a first FinFET transistor 223 and a second FinFET transistor 229.

The SOI base 201 may provide a base for formation of one or more SOI transistors of various types as described herein. The SOI base 201 may be the same or substantially similar as described herein. The first moat 210 may enclose a first bias region 112 of the second doped layer 204 and electrically isolate the first bias region 112 from other areas of the second doped layer 204. The first moat 210 may be the same or substantially similar as described herein. The first bias region 112 may be biased to a specific potential, when insulated from other areas of the second doped layer 204. The first bias region 112 may be biased by electrically coupling the first bias region 112 to the current source 104 via a conductive contact 205 and a first substrate contact 206. By connecting the first bias region 112, the first gate 226, the second gate 232, and the second back gate 233 to the current source, a voltage difference of approximately zero may be maintained between the first and second gate 226, 232, and the first and second back gate 227, 233.

Local substrate contacts placed within the bias regions may bias the substrate to a local fixed potential to help control performance and matching of devices within the insulated first bias region. The first bias region 112 and the first substrate contact 206 may be the same or substantially similar as described herein. The area of the second doped layer 204 outside of the first bias region 112 may also have a bias via the ground substrate contact 207. The ground substrate contact may be the same or substantially similar as described herein.

The first and second FinFET transistors 223, 229 may be the same or substantially similar to the FinFET transistors as described herein. The first and second FinFET transistors 223, 229 may be positioned above the buried oxide layer 208 and the first bias region 112. The first FinFET transistor 223 may include a first drain 224, a first source 228, a first body 225, and a first gate 226. The first body 225 may be between the first drain 224 and first source 228. The first body 225 may have at least a top side and bottom side, the bottom side directly contacting the buried oxide layer 208. The first drain 224 and the first gate 226 may be electrically coupled to one another, to the first bias region 112, and to a current source 104. The first source 228 may be electrically coupled to a ground reference 107.

The second FinFET transistor 229 may include a second drain 230, a second source 234, a second body 231, and a second gate 232. The second gate 232 may be electrically coupled to the first gate 226, the first drain 224, and the first bias region 112. The second body 231 may be between the first drain 230 and first source 234. The second body 231 may have at least a top side and bottom side, the bottom side directly contacting the buried oxide layer 208. The second drain 230 may be electrically coupled to a circuit load 122. The second source 234 may be electrically coupled to the ground reference 107.

By biasing the first bias region 112 and coupling the first and second gates 226, 232 to the first bias region 112. A first back gate 227 and a second back gate 233 may be created on the bottom side of the first and second body 225, 231. All four gate sides of the FinFET may now have approximately equal potential, which may give a better control over the gate to source voltage. The first gate 226, the first back gate 227, the second gate 232 and the second back gate 233 may have approximately equal potential and may increase performance for the first and second FDSOI 211, 217.

The cross section depicts first and second FinFET transistors 223, 229 which are NFET transistors. In embodiments, the transistors may be PFET transistors as described herein.

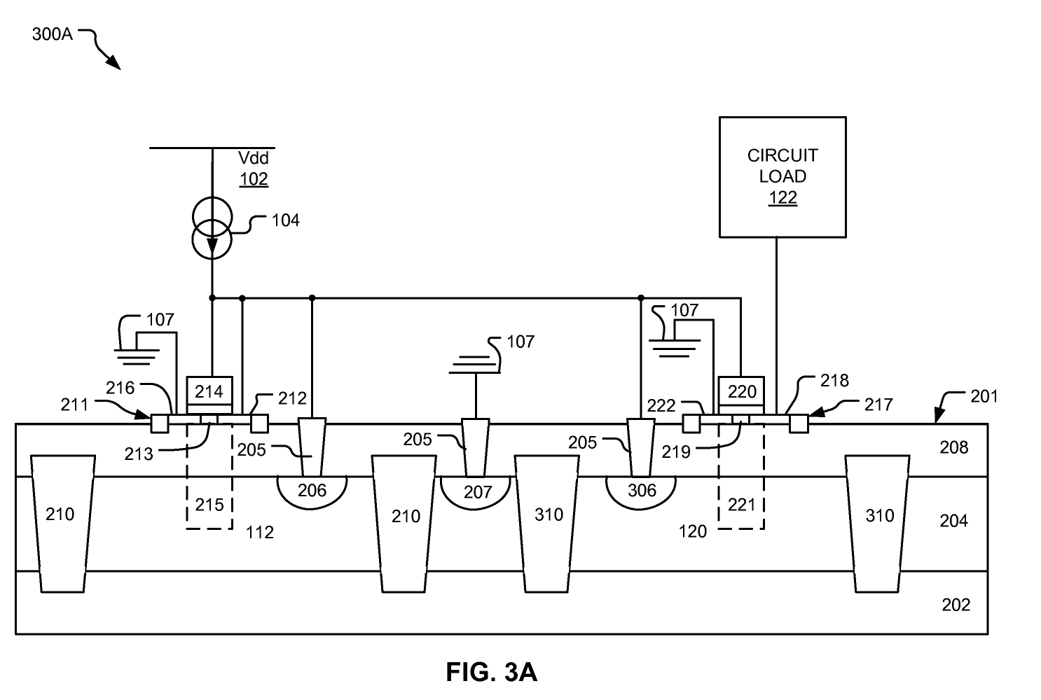

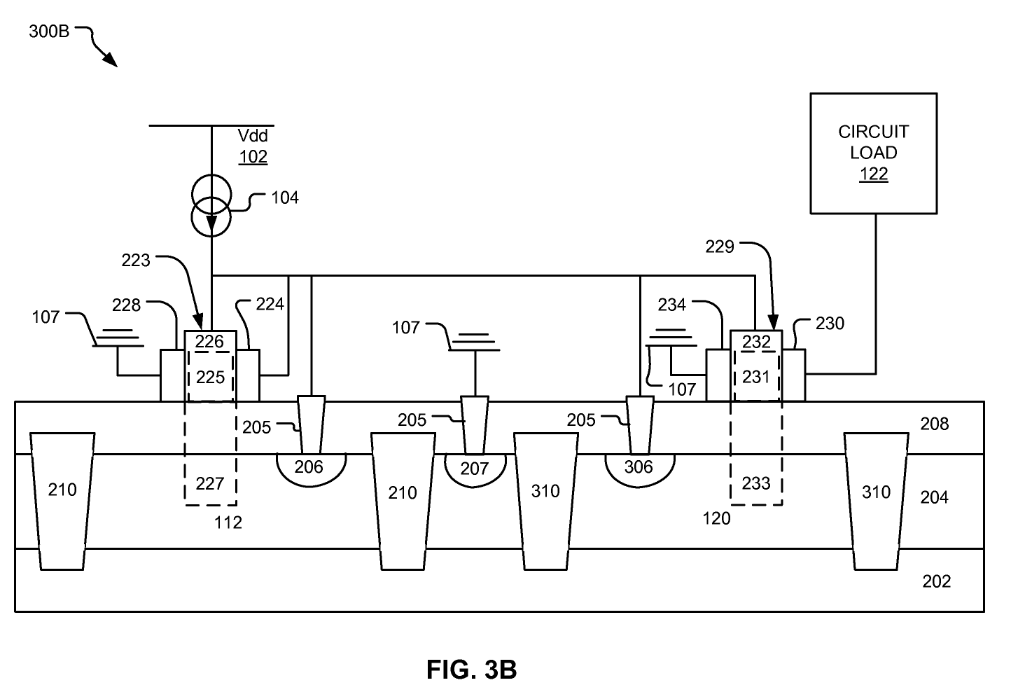

Referring now to FIG. 3A, a cross section view of a semiconductor chip 300A having a circuit on an SOI base 201 is depicted according to embodiments of the present disclosure. The cross section may include an SOI base 201 having a first doped layer 202, a second doped layer 204, and a buried oxide layer 208. The second doped layer 204 may include a first moat 210, a first bias region 112, and a first substrate contact 206. The second doped layer 204 may also include a second moat 310, a second bias region 120, and a second substrate contact 306. The cross section may include a first FDSOI transistor 211 and a second FDSOI transistor 217.

The SOI base 201 may provide a base for formation of one or more SOI transistors of various types as described herein. The SOI base 201 may be the same or substantially similar as described herein. The first moat 210 may enclose a first bias region 112 of the second doped layer 204 and electrically isolate the first bias region 112 from other areas of the second doped layer 204. The first moat 210 may be the same or substantially similar as described herein. The first bias region 112 may be biased to a specific potential when insulated from other areas of the second doped layer 204. The first bias region 112 may be biased by electrically coupling the first bias region 112 to the current source 104 via a conductive contact 205 and first substrate contact 206 as described herein. By connecting the first bias region 112, the first gate 214, the second gate 220, the first back gate 215, and the second back gate 221 to the current source 104, a voltage difference of approximately zero may be maintained between the first and second gate 214, 220, and the first and second back gate 215, 221. The first bias region 112 and the first substrate contact 206 may be the same or substantially similar as described herein.

The second moat 310 may enclose a second bias region 120 of the second doped layer 204 and electrically isolate the second bias region 120 from other areas of the second doped layer 204. The second bias region 120 may be biased to a specific potential when insulated from other areas of the second doped layer 204. The second bias region 120 may be biased by electrically coupling the second bias region 120 to the current source 104 which induces a specific voltage. The second bias region 120 may be coupled via a conductive contact 205 and a second substrate contact 306 as described herein. The second bias region 120 and the second substrate contact 306 may be the same or substantially similar as the first bias region 112 and the first substrate contact 206 as described herein. The area of the second doped layer 204 outside of the first and second bias regions 112, 120 may also have a bias via the ground substrate contact 207. The ground substrate contact may be the same or substantially similar as described herein.

The first and second FDSOI transistors 211, 217 may be the same or substantially similar to the FDSOI transistors as described herein. The first FDSOI transistor 211 may be positioned above the buried oxide layer 208 and the first bias region 112. The second FDSOI transistor 217 may be positioned above the buried oxide layer 208 and the second bias region 120. The first FDSOI transistor 211 may include a first drain 212, a first source 216, a first body 213, and a first gate 214. The first drain 212 and the first gate 214 may be electrically coupled to one another, to the first bias region 112, to the second bias region 120 and to the current source 104. The first source 216 may be electrically coupled to a ground reference 107.

The second FDSOI transistor 217 may include a second drain 218, a second source 222, a second body 219, and a second gate 220. The second gate 220 may be electrically coupled to the first gate 214, the first drain 212, the second bias region 120 and the first bias region 112. The second drain 218 may be electrically coupled to a circuit load 122. The second source 222 may be electrically coupled to the ground reference 107.

By biasing the first bias region 112 and the second bias region 120 to a specific potential induced by the current source 104, and electrically coupling the first and second gates 214, 220 to the first and second bias regions 112, 120, a first back gate 215 and a second back gate 221 may be created on the bottom side of the first and second body 213, 219. The first and second bias regions 112, 120 may act as gate electrodes and the buried oxide layer 208 may act as a gate dielectric. The top and bottom sides of the FDSOI may have approximately equal potential, which may give a better control over the gate to source voltage. The first gate 214, the first back gate 215, the second gate 220 and the second back gate 221 may have approximately equal potential and may increase performance for the first and second FDSOI 211, 217. The increased performance may result from a reduction in threshold voltage of the transistor to form a channel between the source and the drain.

The cross section depicts first and second FDSOI transistors 211, 217 which are NFET transistors. In embodiments, the transistors may be PFET transistors as described herein.

Referring now to FIG. 3B, a cross section view of a semiconductor chip 300B having a circuit on an SOI base 201 is depicted according to embodiments of the present disclosure. The cross section may include an SOI base 201 having a first doped layer 202, a second doped layer 204, and a buried oxide layer 208. The second doped layer 204 may include a first moat 210, a first bias region 112, and a first substrate contact 206. The second doped layer 204 may also include a second moat 310, a second bias region 120, and a second substrate contact 306. The cross section may include a first FinFET transistor 223 and a second FinFET transistor 229.

The SOI base 201 may provide a base for formation of one or more SOI transistors of various types as described herein. The SOI base 201 may be the same or substantially similar as described herein. The first moat 210 may enclose a first bias region 112 of the second doped layer 204 and electrically isolate the first bias region 112 from other areas of the second doped layer 204. The first moat 210 may be the same or substantially similar as described herein. The first bias region 112 may be biased to a specific potential when insulated from other areas of the second doped layer 204. The first bias region 112 may be biased by electrically coupling the first bias region 112 to the current source 104 which induces a specific potential. The first bias region may be electrically coupled to the current source 104 via a conductive contact 205 and a first substrate contact 206 as described herein. The first bias region 112 and the first substrate contact 206 may be the same or substantially similar as described herein.

The second moat 310 may enclose a second bias region 120 of the second doped layer 204 and electrically isolate the second bias region 120 from other areas of the second doped layer 204. The second bias region 120 may be biased to a specific potential when electrically isolated from other areas of the second doped layer 204. The second bias region 120 may be biased by electrically coupling the second bias region 120 to the current source 104 and inducing a specific potential. The second bias region 120 may be electrically coupled to the current source 104 via a conductive contact 205 and a second substrate contact 306 as described herein. The second bias region 120 and the second substrate contact 306 may be the same or substantially similar as the first bias region 112 and the first substrate contact 206 as described herein. The area of the second doped layer 204 outside of the first and second bias regions 112, 120 may also have a bias via the ground substrate contact 207. The ground substrate contact 207 may be the same or substantially similar as described herein.

The first and second FinFET transistors 223, 229 may be the same or substantially similar to the FinFET transistors as described herein. The first FinFET transistor 223 may be positioned above the buried oxide layer 208 and the first bias region 112. The second FinFET transistor 229 may be positioned above the buried oxide layer 208 and the second bias region 120. The first FinFET transistor 223 may include a first drain 224, a first source 228, a first body 225, and a first gate 226. The first drain 224 and the first gate 226 may be electrically coupled to one another, to the first bias region 112, to the second bias region 120 and to a current source 104. The first source 228 may be electrically coupled to a ground reference 107.

The second FinFET transistor 229 may include a second drain 230, a second source 234, a second body 231, and a second gate 232. The second gate 232 may be electrically coupled to the first gate 226, the first drain 224, the second bias region 120 and the first bias region 112. The second drain 230 may be electrically coupled to a circuit load 122. The second source 234 may be electrically coupled to the ground reference 107.

By biasing the first bias region 112 and the second bias region 120 to a specific potential induced by the current source 104, and coupling the first and second gates 226, 232 to the first and second bias regions 112, 120. A first back gate 227 and a second back gate 233 may be created at the bottom side of the first and second body 225, 231 with the buried oxide layer acting as a gate dielectric and the first and second doped regions 112, 120 acting as gate electrodes. The all four sides of the gate on the FinFETs may now have approximately equal potential, which may give a better control over the gate to source voltage. A voltage difference between the first gate 226, the first back gate 227, the second gate 232 and the second back gate 233 may be approximately zero and may improve performance performance for the first and second FinFET 223, 229.

The cross section depicts first and second FinFET transistors 223, 229 which are NFET transistors. In embodiments, the transistors may be PFET transistors as described herein.

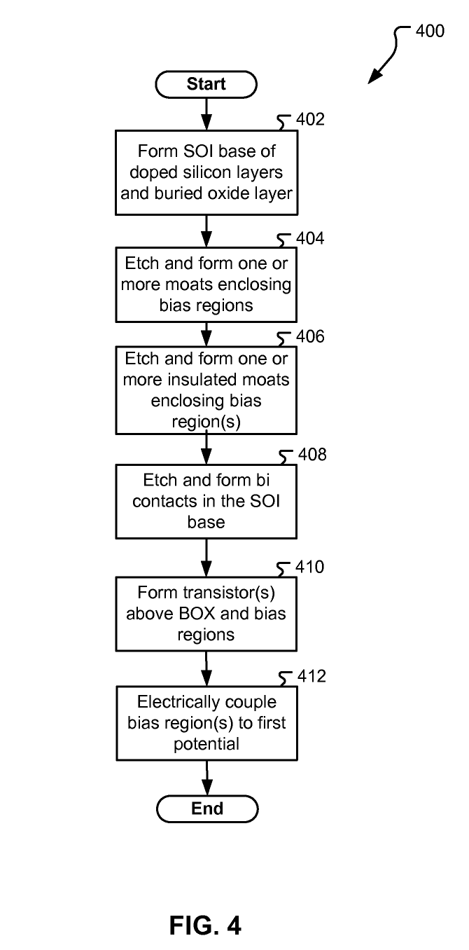

Referring now to FIG. 4, a flowchart of a method 400 of manufacturing a semiconductor chip is depicted according to embodiments of the present disclosure. In operation 402, an SOI base may be formed. The SOI base may be the same or substantially similar as described herein. Forming the SOI base may include forming a first doped layer, forming a second doped layer directly on the first doped layer and forming a buried oxide layer directly on the second doped layer. The first and second doped layers may be the same or substantially similar as described herein. The first and second doped layers may be constructed from silicon, and may be formed epitaxially, or by other suitable method. The buried oxide layer may be the same or substantially similar as described herein.

In operation 404, one or more moats may be etched and formed in the SOI base. The one or more moats may be the same or substantially similar as the first and second moats as described herein. The one or more moats may be formed by etching trenches isolating regions of the second doped layer in the SOI base. The trenches may be filled with insulating material to form insulated regions in the SOI base. The moats may define the bias regions, as described herein. In embodiments, a first moat may be formed enclosing a first bias region of the second doped layer, the first moat electrically isolating the first bias region from other areas of the second doped layer. In embodiments, a first moat and a second moat may be formed enclosing a first and second bias region of the second doped layer.

In operation 406, substrate contacts may be formed in the SOI base. The substrate contacts may be the same or substantially similar as described herein. The substrate contacts may be included in the second doped layer to bias regions of the SOI base as described herein. The substrate contacts may be formed by any suitable method. In embodiments the substrate contacts may be formed by etching one or more holes through the buried oxide layer and to the second doped layer. The one or more hold may be filled with substrate contact material made from doped silicon, or other conductive material as described herein.

In operation 410, transistors may be formed above the buried oxide layers and the bias regions. The transistors may be the same or substantially similar as described herein. In embodiments, a first transistor may be formed above the buried oxide layer and the first bias region. The first transistor may include a first drain, a first source, a first body, and a first gate. The first body may be formed between the first drain and first source. The first body may have at least a top side and bottom side, the bottom side directly contacting the buried oxide layer.

The first drain and the gate may be electrically coupled to one another, to the first bias region, and to a current source. The first source may be electrically coupled to one of a first potential or a ground reference. In embodiments, a second transistor may be formed above the buried oxide layer and the first bias region. The second transistor may include a second drain, a second source, and a second gate, the second gate may be electrically coupled to the first gate, the first drain, and the first bias region. The second drain may be electrically coupled to a circuit load, and the second source may be electrically coupled to one of the first potential or the ground reference. In certain embodiments, the second transistor may be formed above the buried oxide layer and the second bias region.

In operation 412, the bias regions may be electrically coupled to a current source. The bias regions may be biased to a specific potential, induced by the current source, to create a back-gate for each transistor as described herein. Each transistor above the bias region may have a back gate on the bottom side of the body. For example, the first transistor may have a first back gate on the bottom side of the first body, the first back gate including the buried oxide layer as a gate dielectric and the first bias region as a gate electrode.

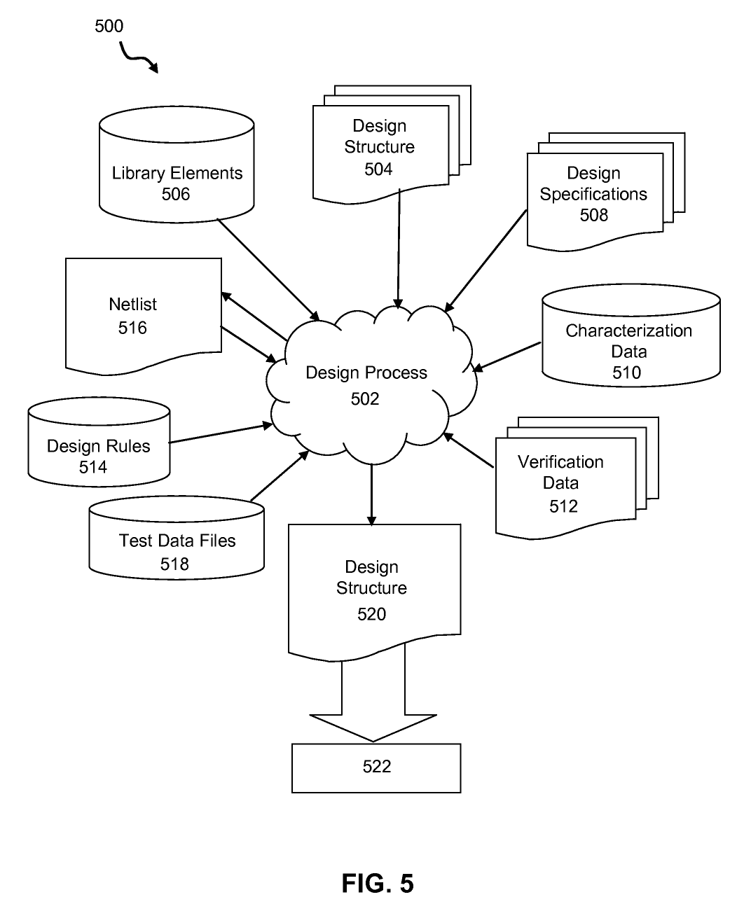

FIG. 5 illustrates multiple such design structures including an input design structure 504 that is preferably processed by a design process 502. Design structure 504 may be a logical simulation design structure generated and processed by design process 502 to produce a logically equivalent functional representation of a hardware device. Design structure 504 may also or alternatively comprise data and/or program instructions that when processed by design process 502, generate a functional representation of the physical structure of a hardware device. Whether representing functional and/or structural design features, design structure 504 may be generated using electronic computer-aided design (ECAD) such as implemented by a core developer/designer.

When encoded on a machine-readable data transmission, gate array, or storage medium, design structure 504 may be accessed and processed by one or more hardware and/or software modules within design process 502 to simulate or otherwise functionally represent an electronic component, circuit, electronic or logic module, apparatus, device, or system such as those shown herein. As such, design structure 504 may comprise files or other data structures including human and/or machine-readable source code, compiled structures, and computer-executable code structures that when processed by a design or simulation data processing system functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 502 preferably employs and incorporates hardware and/or software modules for synthesizing, translating, or otherwise processing a design/simulation functional equivalent of the components, circuits, devices, or logic structures shown herein to generate a Netlist 516 which may contain design structures such as design structure 504. Netlist 516 may comprise, for example, compiled or otherwise processed data structures representing a list of wires, discrete components, logic gates, control circuits, I/O devices, models, etc. that describes the connections to other elements and circuits in an integrated circuit design. Netlist 516 may be synthesized using an iterative process in which netlist 516 is resynthesized one or more times depending on design specifications and parameters for the device. As with other design structure types described herein, netlist 516 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 502 may include hardware and software modules for processing a variety of input data structure types including Netlist 516. Such data structure types may reside, for example, within library elements 506 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 408, characterization data 510, verification data 512, design rules 514, and test data files 518 which may include input test patterns, output test results, and other testing information. Design process 502 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 502 without deviating from the scope and spirit of the invention. Design process 502 may also include modules for performing standard circuit design processes such as timing analysis, verification, design rule checking, place and route operations, etc. Design process 502 employs and incorporates logic and physical design tools such as HDL compilers and simulation model build tools to process design structure 504 together with some or all of the depicted supporting data structures along with any additional mechanical design or data (if applicable), to generate a second design structure 520. Design structure 520 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures).

Similar to design structure 504, design structure 520 preferably comprises one or more files, data structures, or other computer-encoded data or instructions that reside on transmission or data storage media and that when processed by an ECAD system generate a logically or otherwise functionally equivalent form of one or more of the embodiments of the invention shown herein. In one embodiment, design structure 520 may comprise a compiled, executable HDL simulation model that functionally simulates the devices shown herein.

Design structure 520 may also employ a data format used for the exchange of layout data of integrated circuits and/or symbolic data format (e.g. information stored in a GDSII (GDS2), GL1, OASIS, map files, or any other suitable format for storing such design data structures). Design structure 520 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown herein. Design structure 520 may then proceed to a stage 522 where, for example, design structure 520: proceeds to tape-out, is released to manufacturing, is released to a mask house, is sent to another design house, is sent back to the customer, etc.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

1. A semiconductor chip device comprising:
a silicon on insulator (SOI) base including:
a semiconductor substrate having a first doped layer and a second doped layer directly on the first doped layer;
a buried oxide layer directly on the second doped layer; and
a first moat electrically isolating a first bias region of the second doped layer from other areas of the second doped layer, wherein the first bias region is electrically coupled to a current source;
a first transistor formed above the buried oxide layer and the first bias region, the first transistor including:
a first drain;
a first source;
a first body between the first drain and first source, the first body having at least a top side and bottom side, the bottom side directly contacting the buried oxide layer;
a first gate on at least the top side of the first body, the first gate electrically coupled to the current source; and
a first back gate on the bottom side of the first body, the first back gate including the buried oxide layer as a gate dielectric and the first bias region as a gate electrode; and
a voltage device formed above the buried oxide layer and the first bias region, the voltage device electrically coupled to the first back gate and the first gate, the voltage device configured to maintain a voltage difference between the first gate and the first back gate.

2. The device of claim 1, wherein the voltage difference between the first gate and the first back gate is approximately zero.

3. The device of claim 1, wherein the first bias region includes a first substrate contact, wherein the first bias region is electrically coupled to the current source via the first substrate contact.

4. The device of claim 3, wherein the first substrate contact has a first dopant concentration greater than a first bias dopant concentration of the first bias region.

5. The device of claim 1, wherein the voltage device is a second transistor formed above the buried oxide layer and the first bias region, the second transistor including:
a second drain;
a second source;
a second body between the second drain and second source, the second body having at least a top side and bottom side, the bottom side directly contacting the buried oxide layer;
a second gate on at least the top side of the second body; and
a second back gate on the bottom side of the second body, the second back gate including the buried oxide layer as a gate dielectric and the first bias region as a gate electrode;
wherein the first drain, the first gate, and the second gate are electrically coupled to one another, to the first bias region, and to the current source, and wherein the first source and second source are electrically coupled to one of a ground reference or a first potential, and wherein the second drain is electrically coupled to a circuit load;
wherein the first transistor receives a first current from the current source and the circuit load receives a second current, based on the first current, from the second transistor.

6. The device of claim 5, wherein the SOI base further includes a second moat electrically isolating a second bias region of the second doped layer from other areas of the second doped layer, and wherein the second bias region is electrically coupled to the current source.

7. The device of claim 6, wherein the second transistor is formed above the buried oxide layer and the second bias region, and wherein the second gate is electrically coupled to the first gate, the first drain, the first bias region, and the second bias region.

8. The device of claim 6, wherein the second bias region includes a second substrate contact, wherein the first drain, the first gate, the current source, and the second gate are electrically coupled to the second bias region via the second substrate contact.

9. The device of claim 5, wherein the first and second transistors are fully depleted SOI transistors.

10. The device of claim 5, wherein the first and second transistors are FinFETs.

11-18. (canceled)

19. A design structure readable by a machine used in design, manufacture, or simulation of an integrated circuit, the design structure comprising:
a silicon on insulator (SOI) base including:
a semiconductor substrate having a first doped layer and a second doped layer directly on the first doped layer;
a buried oxide layer directly on the second doped layer; and
a first moat electrically isolating a first bias region of the second doped layer from other areas of the second doped layer, wherein the first bias region is electrically coupled to a current source;
a first transistor formed above the buried oxide layer and the first bias region, the first transistor including:
a first drain;
a first source;
a first body between the first drain and first source, the first body having at least a top side and bottom side, the bottom side directly contacting the buried oxide layer;
a first gate on at least the top side of the first body, the first gate electrically coupled to the current source; and
a first back gate on the bottom side of the first body, the first back gate including the buried oxide layer as a gate dielectric and the first bias region as a gate electrode; and
a voltage device formed above the buried oxide layer and the first bias region, the voltage device electrically coupled to the first back gate and the first gate, the voltage device configured to maintain a voltage difference between the first gate and the first back gate.

20. The design structure of claim 18, wherein the design structure resides on storage medium as a data format used for the exchange of layout data of integrated circuits.
